(19) United States
(12) Patent Application Publication
(10) Pub. No.: US 2026/0052948 A1
(43) Pub. Date: Feb. 19, 2026

(54) SEMICONDUCTOR DEVICE AND METHOD FOR MANUFACTURING THE SAME

(71) Applicant: Electronics and Telecommunications Research Institute, Daejeon (KR)

(72) Inventor: Hoemin KWAK, Daejeon (KR)

(73) Assignee: Electronics and Telecommunications Research Institute, Daejeon (KR)

(21) Appl. No.: 19/298,279

(22) Filed: Aug. 13, 2025

(30) Foreign Application Priority Data
Aug. 14, 2024 (KR) 10-2024-0109108
Jan. 24, 2025 (KR) 10-2025-0011173

(51) Int. Cl. H01L 21/683; B32B 3/30; B32B 7/12; B32B 9/00; B32B 9/04; B32B 15/04; B32B 37/12; B32B 37/18; H01L 21/02; H01L 21/78

(52) U.S. Cl. CPC H01L 21/6835; B32B 3/30; B32B 7/12; B32B 9/005; B32B 9/041; B32B 15/04; B32B 37/12; B32B 37/18; H01L 21/0243; H01L 21/02499; H01L 21/0254; H01L 21/7806; B32B 2250/02; B32B 2311/00; B32B 2315/02; B32B 2457/14; H01L 2221/68368

(57) ABSTRACT

A semiconductor device according to some embodiments includes: a transfer substrate, a semiconductor layer, and an adhesive layer between the transfer substrate and the semiconductor layer. The adhesive layer includes a lower portion and first and second protrusions, and the semiconductor layer comprises an upper portion and first and second protrusions. The first and second protrusions of the adhesive layer are in contact with the upper portion of the semiconductor layer, the first and second protrusions of the semiconductor layer are in contact with the lower portion of the adhesive layer, the first protrusion of the adhesive layer is disposed between the first and second protrusions of the semiconductor layer, and the second protrusion of the semiconductor layer is disposed between the first and second protrusions of the semiconductor layer.

### CROSS-REFERENCE TO RELATED APPLICATIONS

This U.S. non-provisional patent application claims priority under 35 U.S.C. § 119 of Korean Patent Application Nos. 10-2024-0109108, filed on Aug. 14, 2024, and 10-2025-0011173, filed on Jan. 24, 2025, the entire contents of which are hereby incorporated by reference.

### BACKGROUND

The present disclosure herein relates to a semiconductor device and a method for manufacturing the same, and more particularly, to a semiconductor device, in which a semiconductor layer and an adhesive layer include protrusions, and a method for manufacturing the same.

As a method for manufacturing semiconductor devices, a technology in which a thin film-shaped semiconductor device is manufactured to be transferred is being utilized. Various methods are being studied to easily separate thin films from a substrate so as to transfer the semiconductor device grown in the form of a thin film.

### SUMMARY

The present disclosure provides a semiconductor device having electrical characteristics and reliability.

The present disclosure also provides a method for manufacturing a semiconductor device capable of preventing process defects and improving yield.

Some embodiments of the inventive concept provide a semiconductor device including: a transfer substrate; a semiconductor layer disposed at a level higher than a level of the transfer substrate; and an adhesive layer between the transfer substrate and the semiconductor layer, wherein the adhesive layer includes a lower portion and first and second protrusions, each of which is disposed at a level higher than a level of the lower portion of the adhesive layer, and the semiconductor layer comprises an upper portion and first and second protrusions, each of which is disposed at a level lower than a level of the upper portion of the semiconductor layer, wherein the first and second protrusions of the adhesive layer are in contact with the upper portion of the semiconductor layer, the first and second protrusions of the semiconductor layer are in contact with the lower portion of the adhesive layer, the first protrusion of the adhesive layer is disposed between the first and second protrusions of the semiconductor layer, and the second protrusion of the semiconductor layer is disposed between the first and second protrusions of the semiconductor layer.

In some embodiment of the inventive concept, a semiconductor device includes: a transfer substrate; an adhesive layer that is in contact with the transfer substrate; and a semiconductor layer that is in contact with the adhesive layer, wherein the adhesive layer includes a lower portion and first and second protrusions disposed to protrude from the lower portion of the adhesive layer, wherein the first and second protrusions of the adhesive layer are spaced apart from each other, the semiconductor layer is configured to cover the first and second protrusions of the adhesive layer, and a portion of the semiconductor layer is disposed between the first and second protrusions of the adhesive layer.

In some embodiment of the inventive concept, a method for manufacturing a semiconductor device includes: patterning a growth substrate to form a first protrusion pattern and a second protrusion pattern; forming an isolation layer covering the first and second protrusion patterns, wherein the isolation layer comprises a first recessed part disposed between the first and second protrusion patterns; forming a semiconductor core on the first recessed part of the isolation layer; growing the semiconductor color to form a semiconductor layer, wherein a portion of the semiconductor layer is disposed at a level higher than a level of the isolation layer; and separating the semiconductor layer from the isolation layer.

### BRIEF DESCRIPTION OF THE FIGURES

The accompanying drawings are included to provide a further understanding of some embodiments of the inventive concept, and are incorporated in and constitute a part of this specification. The drawings illustrate some embodiments of the inventive concept and, together with the description, serve to explain principles. In the drawings:

FIG. 1A is a plan view of a semiconductor device according to some embodiments;

FIG. 1B is a cross-sectional view taken along line I-I′ of FIG. 1A;

FIG. 1C is an enlarged view of an area A of FIG. 1B;

FIGS. 2A, 2B, 2D, 2F, 2G, 2H, 2J, 2K, 2M and 2N are views for explaining a method for manufacturing a semiconductor device according to FIGS. 1A to 1C;

FIG. 2C is a cross-sectional view taken along line I-I′ of FIG. 2B;

FIG. 2E is a cross-sectional view taken along line I-I′ of FIG. 2D;

FIG. 2I is an enlarged view of an area B of FIG. 2H;

FIG. 2L is an enlarged view of an area C of FIG. 2K;

FIG. 3 is a view of a semiconductor device according to some embodiments;

FIG. 4 is a view of a semiconductor device according to some embodiments;

FIG. 5A is a view of a semiconductor device according to some embodiments;

FIG. 5D is an enlarged view of an area D of FIG. 5A;

FIG. 6A is a plan view of a semiconductor device according to some embodiments;

FIG. 6B is a cross-sectional view taken along line A-A′ of FIG. 6A; and

FIG. 6C is a cross-sectional view taken along line B-B′ of FIG. 6A.

### DETAILED DESCRIPTION

Hereinafter, a semiconductor device and a method for manufacturing the same according to some embodiments of the inventive concept will be described in detail with reference to the drawings.

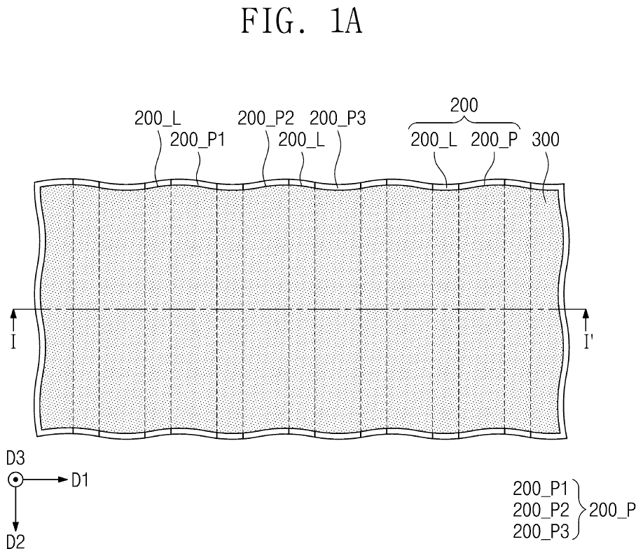

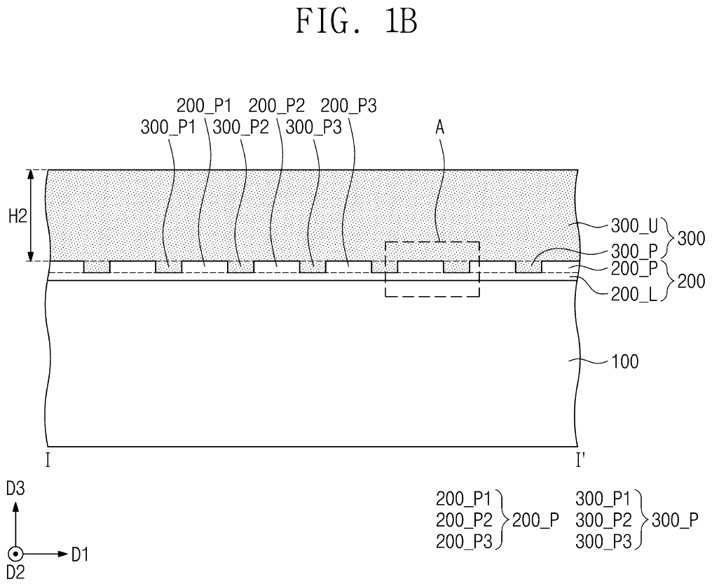

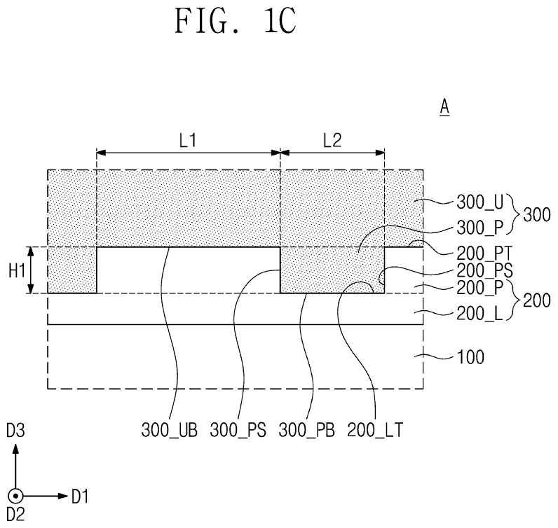

FIG. 1A is a plan view of a semiconductor device according to some embodiments. FIG. 1B is a cross-sectional view taken along line I-I′ of FIG. 1A. FIG. 1C is an enlarged view of an area A of FIG. 1B.

Referring to FIGS. 1A, 1B, and 1C, a transfer substrate 100 may be provided. In some embodiments, the transfer substrate 100 may be a semiconductor substrate. For example, the transfer substrate 100 may include silicon, germanium, silicon-germanium, GaP, or GaAs. In some embodiments, the transfer substrate 100 may be a silicon-on-insulator (SOI) substrate or a germanium-on-insulator (GOI) substrate.

The transfer substrate 100 may have the form of a plate extending along a plane expanded in a first direction D1 and a second direction D2. The first direction D1 and the second direction D2 may intersect each other. For example, the first direction D1 and the second direction D2 may be horizontal directions that are orthogonal to each other.

An adhesive layer 200 may be disposed on the transfer substrate 100. The adhesive layer 200 may be in contact with a top surface of the transfer substrate 100. The adhesive layer 200 may include a lower portion 200_L and protrusions 200_P.

The protrusions 200_P of the adhesive layer 200 may include a first protrusion 200_P1, a second protrusion 200_P2, and a third protrusion 200_P3. The lower portion 200_L and the protrusions 200_P of the adhesive layer 200 may be connected to each other without any boundary so as to be integrated with each other. The protrusions 200_P of the adhesive layer 200 may protrude from the lower portion 200_L of the adhesive layer 200.

The protrusions 200_P of the adhesive layer 200 may be arranged at the same level. The lower portion 200_L of the adhesive layer 200 may be disposed at a level lower than that of each of the protrusions 200_P. The lower portion 200_L of the adhesive layer 200 may be in contact with the top surface of the transfer substrate 100.

The protrusions 200_P of the adhesive layer 200 may be spaced apart from the transfer substrate 100 in a third direction D3. The third direction D3 may intersect the first direction D1 and the second direction D2. For example, the third direction D3 may be a vertical direction that is orthogonal to the first direction D1 and the second direction D2.

The first to third protrusions 200_P1, 200_P2, and 200_P3 of the adhesive layer 200 may be sequentially arranged in the first direction D1. The first to third protrusions 200_P1, 200_P2, and 200_P3 of the adhesive layer 200 may be spaced apart from each other in the first direction D1. The second protrusion 200_P2 of the adhesive layer 200 may be disposed between the first and third protrusions 200_P1 and 200_P3. The first and third protrusions 200_P1 and 200_P3 of the adhesive layer 200 may be adjacent to the second protrusion 200_P2 in the first direction D1. A distance between the first and second protrusions 200_P1 and 200_P2 of the adhesive layer 200 may be the same as a distance between the second and third protrusions 200_P2 and 200_P3.

In some embodiments, the adhesive layer 200 may include a metal material. For example, the adhesive layer 200 may include Au or Cu. In some embodiments, the adhesive layer 200 may include a polymeric material.

A semiconductor layer 300 may be disposed on the adhesive layer 200. The semiconductor layer 300 may cover the first to third protrusions 200_P1, 200_P2, and 200_P3 of the adhesive layer 200. The semiconductor layer 300 may include a semiconductor material. In some embodiments, the semiconductor layer 300 may include a compound semiconductor material. For example, the semiconductor layer 300 may include GaN.

The semiconductor layer 300 may include an upper portion 300_U and protrusions 300_P. The protrusions 300_P of the semiconductor layer 300 may include a first protrusion 300_P1, a second protrusion 300_P2, and a third protrusion 300_P3. The upper portion 300_U and the protrusions 300_P of the semiconductor layer 300 may be connected to each other to be integrated with each other. The protrusions 300_P of the semiconductor layer 300 may protrude from the upper portion 300_U.

The protrusions 300_P of the semiconductor layer 300 may be arranged at the same level. The upper portion 300_U of the semiconductor layer 300 may be disposed at a level higher than that of each of the protrusions 300_P. The upper portion 300_U of the semiconductor layer 300 may be spaced apart from the lower portion 200_L of the adhesive layer 200 in the third direction D3. The protrusion 300_P of the semiconductor layer 300 may be in contact with the lower portion 200_L of the adhesive layer 200.

The first to third protrusions 300_P1, 300_P2, and 300_P3 of the semiconductor layer 300 may be sequentially arranged in the first direction D1. The first to third protrusions 300_P1, 300_P2, and 300_P3 of the semiconductor layer 300 may be spaced apart from each other in the first direction D1. The second protrusion 300_P2 of the semiconductor layer 300 may be disposed between the first and third protrusions 300_P1 and 300_P3. The first and third protrusions 300_P1 and 300_P3 of the semiconductor layer 300 may be adjacent to the second protrusion 300_P2 in the first direction D1. A distance between the first and second protrusions 300_P1 and 300_P2 of the semiconductor layer 300 may be the same as a distance between the second and third protrusions 300_P2 and 300_P3.

The first protrusion 200_P1 of the adhesive layer 200 may be disposed between the first and second protrusions 300_P1 and 300_P2 of the semiconductor layer 300. The second protrusion 200_P2 of the adhesive layer 200 may be disposed between the second and third protrusions 300_P2 and 300_P3 of the semiconductor layer 300.

The second protrusion 300_P2 of the semiconductor layer 300 may be disposed between the first and second protrusions 200_P1 and 200_P2 of the adhesive layer 200. The third protrusion 300_P3 of the semiconductor layer 300 may be disposed between the second and third protrusions 200_P2 and 200_P3 of the adhesive layer 200.

In a planar view according to FIG. 1A, the protrusions 200_P of the adhesive layer 200 may have a bar shape extending in the second direction D2 and arranged in the first direction D1. The protrusions 300_P of the semiconductor layer 300 may have a bar shape extending in the second direction D2 and arranged in the first direction D1. The protrusions 200_P of the adhesive layer 200 and the protrusions 300_P of the semiconductor layer 300 may be arranged alternately in the first direction D1.

Each of the protrusions 200_P of the adhesive layer 200 may include a top surface 200_PT and a sidewall 200_PS. The lower portion 200_L of the adhesive layer 200 may include a top surface 200_LT. The top surface 200_LT of the lower portion 200_L of the adhesive layer 200 may be disposed at a level lower than that of the top surface 200_PT of the protrusion 200_P of the adhesive layer 200.

The top surface 200_LT of the lower portion 200_L of the adhesive layer 200 may be spaced apart from the top surface 200_PT of the protrusion 200_P of the adhesive layer 200. The sidewall 200_PS of the protrusion 200_P of the adhesive layer 200 may connect the top surface 200_LT of the lower portion 200_L of the adhesive layer 200 to the top surface 200_PT of the protrusion 200_P of the adhesive layer 200.

The protrusion 300_P of the semiconductor layer 300 may include a bottom surface 300_PB and a sidewall 300_PS. The upper portion 300_U of the semiconductor layer 300 may include a bottom surface 300_UB. The bottom surface 300_PB of the protrusion 300_P of the semiconductor layer 300 may be disposed at a level lower than that of the bottom surface 300_UB of the top surface 300_U of the semiconductor layer 300.

The bottom surface 300_UB of the top surface 300_U of the semiconductor layer 300 may be spaced apart from the bottom surface 300_PB of the protrusion 300_P. The sidewall 300_PS of the protrusion 300_P of the semiconductor layer 300 may connect the bottom surface 300_UB of the top surface 300_U of the semiconductor layer 300 to the bottom surface 300_PB of the protrusion 300_P.

The bottom surface 300_UB of the top surface 300_U of the semiconductor layer 300 may be in contact with the top surface 200_PT of the protrusion 200_P of the adhesive layer 200. The bottom surface 300_PB of the protrusion 300_P of the semiconductor layer 300 may be in contact with the top surface 200_LT of the bottom surface 200_L of the adhesive layer 200. The sidewall 300_PS of the protrusion 300_P of the semiconductor layer 300 may be in contact with the sidewall of the protrusion 200_P of the adhesive layer 200.

Thicknesses H1 of the protrusion 200_P of the adhesive layer 200 and the protrusion 300_P of the semiconductor layer 300 may be the same. A thickness H2 of the upper portion 300_U of the semiconductor layer 300 in the third direction D3 may be greater than each of the thicknesses H1 of the protrusion 200_P of the adhesive layer 200 and the protrusion 300_P of the semiconductor layer 300 in the third direction D3. In some embodiments, each of the thicknesses H1 of the protrusion 200_P of the adhesive layer 200 and the protrusion 300_P of the semiconductor layer 300 in the third direction D3 may be greater than about 1 nm and less than about 10 nm.

In some embodiments, a width L1 of the protrusion 200_P of the adhesive layer 200 in the first direction D1 and a width L2 of the top surface 200_LT of the lower portion 200_L of the adhesive layer 200 in the first direction D1 may be greater than 1 μm and less than 10 μm. The width L1 of the protrusion 200_P of the adhesive layer 200 in the first direction D1 may be the same as the width of the bottom surface 300_UB of the top surface 300_U of the semiconductor layer 300 in the first direction D1. The width L2 of the top surface 200_LT of the lower portion 200_L of the adhesive layer 200 in the first direction D1 may be the same as the width of the protrusion 300_P of the semiconductor layer 300 in the first direction D1.

The semiconductor device according to some embodiments may include the protrusion 200_P of the adhesive layer 200 and the protrusion 300_P of the semiconductor layer 300, and thus, the area on which the adhesive layer 200 and the semiconductor layer 300 are in contact with each other may be relatively large. Thus, the adhesion between the transfer substrate 100 and the semiconductor layer 300 may be more stable and easier.

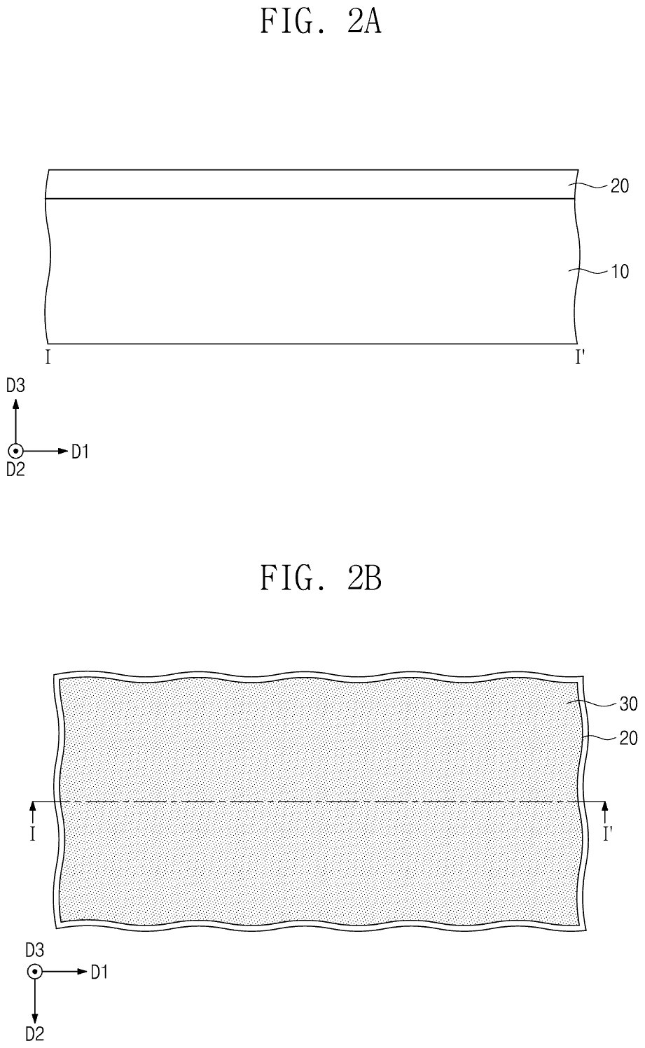

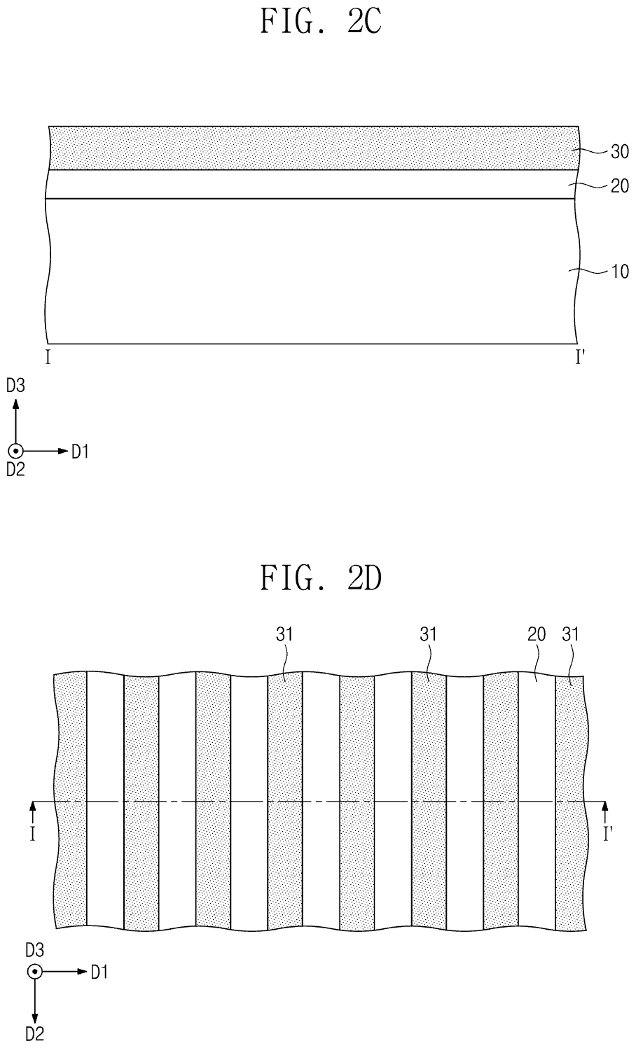

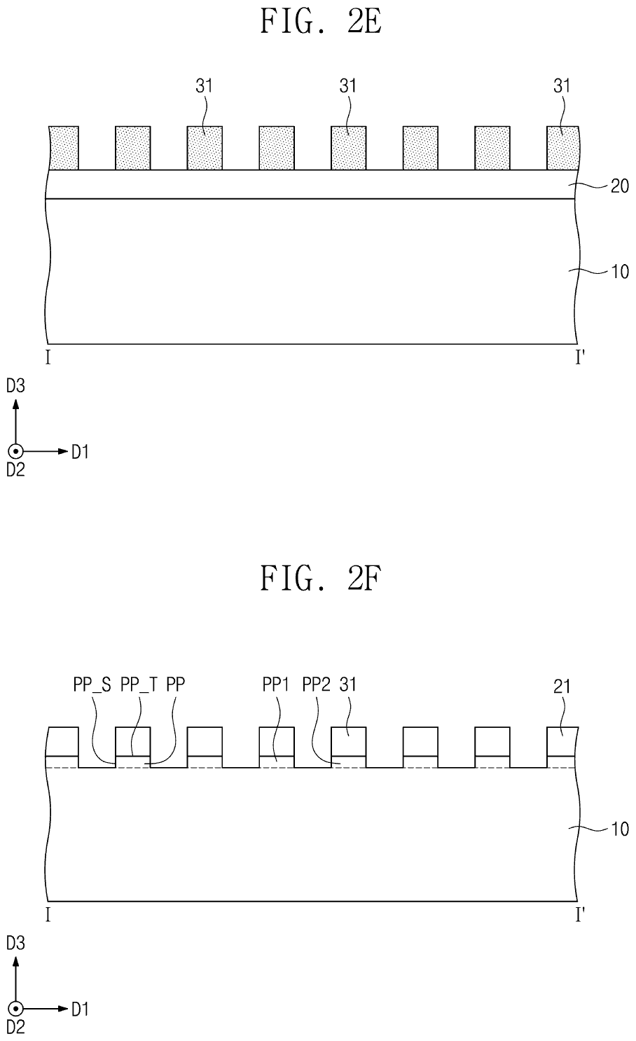

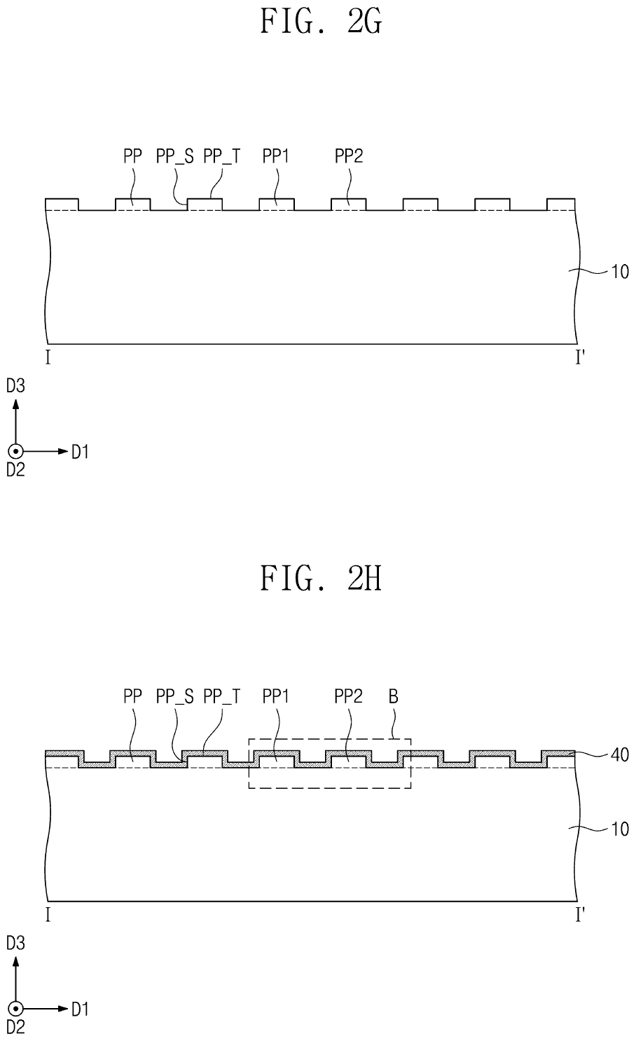

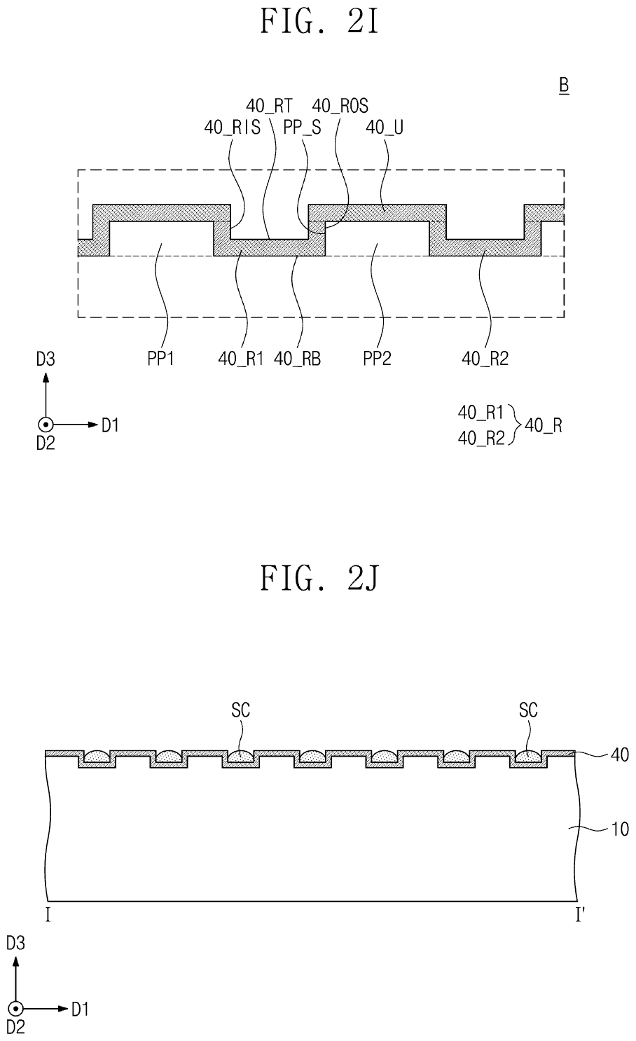

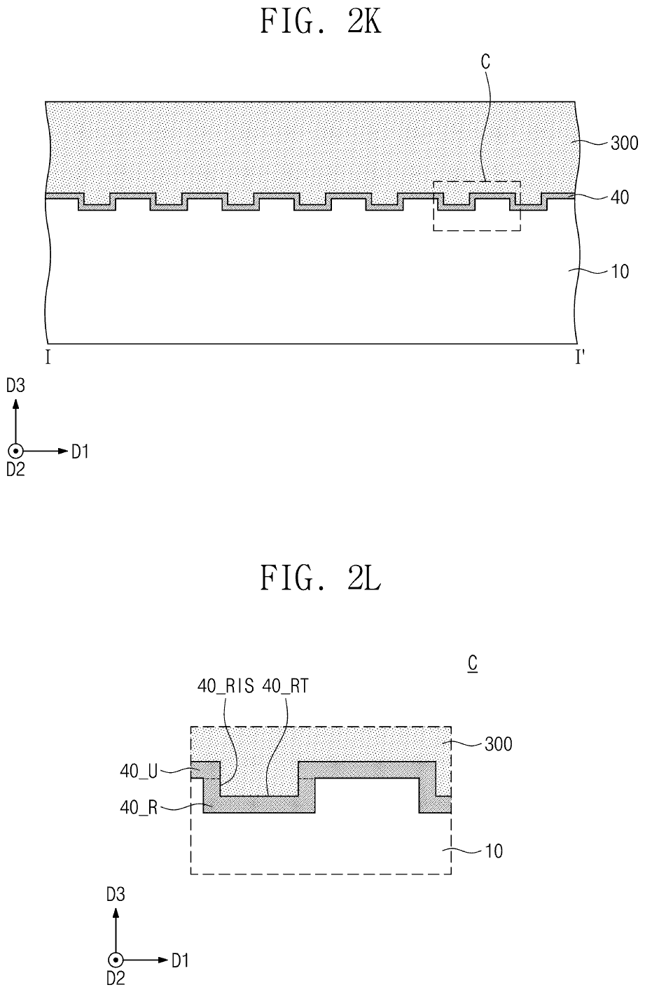

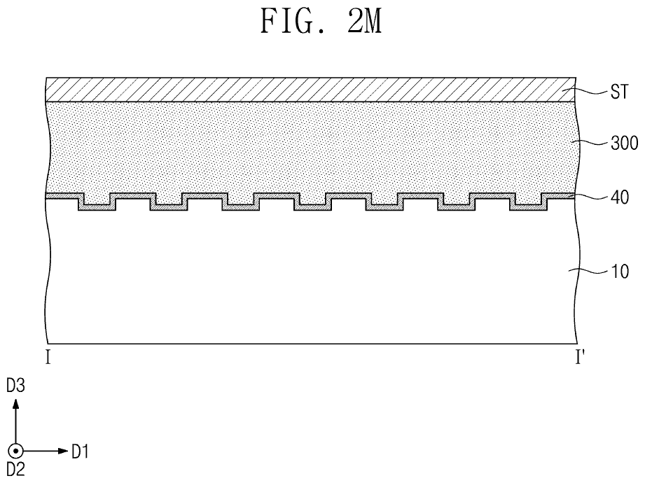

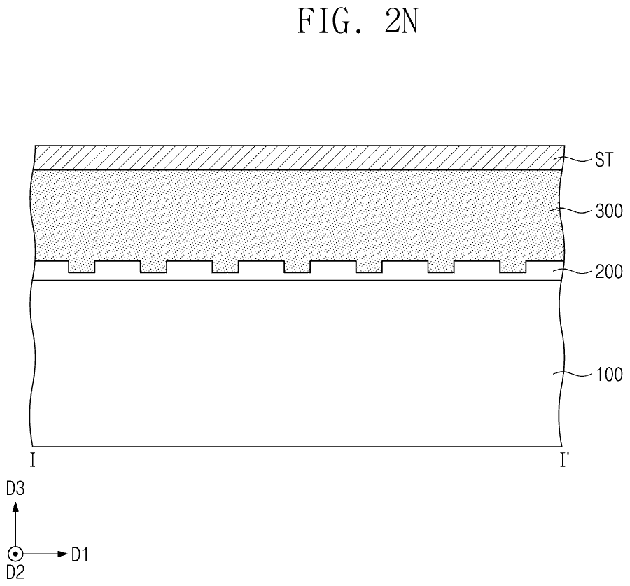

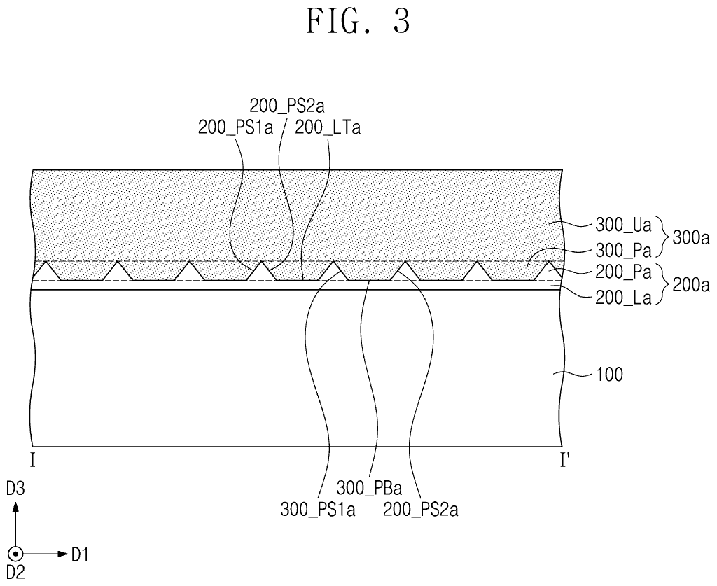

FIGS. 2A, 2B, 2D, 2F, 2G, 2H, 2J, 2K, 2M and 2N are views for explaining a method for manufacturing a semiconductor device according to FIGS. 1A to 1C. FIG. 2C is a cross-sectional view taken along line I-I′ of FIG. 2B. FIG. 2E is a cross-sectional view taken along line I-I′ of FIG. 2D. FIG. 2I is an enlarged view of an area B of FIG. 2H. FIG. 2L is an enlarged view of an area C of FIG. 2K.

Referring to FIG. 2A, a growth substrate 10 may be provided. The growth substrate 10 may be a silicon, sapphire or glass substrate. The growth substrate 10 may be a semiconductor substrate. The growth substrate 10 may include a compound semiconductor material. In some embodiments, the growth substrate 10 may be a silicon substrate. In some embodiments, the growth substrate 10 may be a nitride semiconductor substrate. In some embodiments, a crystal plane of a top surface of the growth substrate 10 may be a (001) plane.

A mask layer 20 may be formed on the growth substrate 10. The mask layer 20 may include a metal material or an insulating material. As an example of the metal material, the mask layer 20 may include Ni, Cr, Ti, or Cu. Forming of the mask layer 20 including the metal material may include performing of an e-beam evaporator process, performing of a sputtering process, or performing of an electroplating process.

As an example of the insulating material, the mask layer 20 may include SiO₂, SiNₓ or HfO₂. The forming of the mask layer 20 including the insulating material may include performing of a chemical vapor deposition (CVD) process or forming of an atomic layer deposition (ALD).

Referring to FIGS. 2B and 2C, a photosensitive film 30 may be formed on the mask layer 20. The photosensitive film 30 may include a photosensitive material. In some embodiments, the forming of the mask layer 20 may be omitted, and the photosensitive film 30 may be formed on the growth substrate 10.

Referring to FIGS. 2D and 2E, the photosensitive film 30 may be patterned to form photosensitive patterns 31. The photosensitive film 30 may be patterned so that a portion of a top surface of the mask layer 20 is exposed. The photosensitive patterns 31 may be arranged in the first direction D1.

Referring to FIG. 2F, the photosensitive patterns 31 may be used as an etching mask to pattern the mask layer 20 and the growth substrate 10, thereby forming mask patterns 21 and protrusion patterns PP. The protrusion patterns PP may include a first protrusion pattern PP1 and a second protrusion pattern PP2. The first and second protrusion patterns PP1 and PP2 may be arranged in the first direction D1. The first and second protrusion patterns PP1 and PP2 may be spaced apart from each other in the first direction D1.

Each of the protrusion patterns PP may include a sidewall PP_S and a top surface PP_T. The sidewall of the protrusion pattern PP may be exposed. The protrusion patterns PP may be arranged in the first direction D1. The protrusion patterns PP may have a bar shape extending in the second direction D2. A distance between the protrusion patterns PP in the first direction D1 may be greater than about 1 μm and less than about 10 μm. A width of each of the protrusion patterns PP in the first direction D1 may be greater than about 1 μm and less than about 10 μm. A thickness of each of the protrusion patterns PP in the third direction D3 may be greater than about 1 nm and less than about 10 nm.

Referring to FIG. 2G, the mask patterns 21 may be removed. The mask patterns 21 may be removed so that the top surface PP_T of the protrusion pattern PP is exposed.

Referring to FIGS. 2H and 21, an isolation layer 40 may be formed on the growth substrate 10 and the protrusion pattern PP. The isolation layer 40 may include a two-dimensional material. For example, the isolation layer 40 may include graphene or hBN. The isolation layer 40 can conformally cover the growth substrate 10 and the protrusion patterns PP.

The isolation layer 40 may include a recessed part 40_R and an upper portion 40_U. The recessed part 40_R of the isolation layer 40 may include a first recessed part 40_R1 and a second recessed part 40_R2. The upper portion 40_U of the isolation layer 40 may be disposed at a level higher than that of the recessed part 40_R. The first recessed part 40_R1 and the second recessed part 40_R2 of the isolation layer 40 may be disposed at the same level.

The first recessed part 40_R1 of the isolation layer 40 may be disposed between the first and second protrusion patterns PP1 and PP2. The first recessed part 40_R1 and the second recessed part 40_R2 of the isolation layer 40 may be spaced apart from each other in the first direction D1. The second protrusion pattern PP2 may be disposed between the first and second recessed parts 40_R1 and 40_R2 of the isolation layer 40. The upper portion 40_U of the isolation layer 40 may connect the first recessed part 40_R1 to the second recessed part 40_R2.

The recessed part 40_R of the isolation layer 40 may include a top surface 40_RT, a bottom surface 40_RB, an inner wall 40_RIS, and an outer wall 40_ROS. The bottom surface 40_RB of the isolation layer 40 may be in contact with the top surface of the growth substrate 10. The outer wall 40_ROS of the recessed part 40_R of the isolation layer 40 may be in contact with the sidewall PP_S of the protrusion pattern PP. The inner wall 40_RIS of the recessed part 40_R of the isolation layer 40 may be spaced apart from the protrusion pattern PP. The inner wall 40_RIS of the recessed part 40_R of the isolation layer 40 may be connected to the top surface 40_RT of the recessed part 40_R. The outer wall 40_ROS of the isolation layer 40 may be connected to the bottom surface 40_RB of the recessed part 40_R.

Referring to FIG. 2J, semiconductor cores SC may be formed on the isolation layer 40. Each of the semiconductor cores SC may include a semiconductor material. For example, the semiconductor core SC may include GaN. The semiconductor core SC may be formed on the top surface 40_RT of the recessed part 40_R (see FIG. 2I) of the isolation layer 40. The semiconductor cores SC may be arranged in the first direction D1. The semiconductor cores SC may be spaced apart from each other in the first direction D1. The isolation layer 40 and the protrusion pattern PP may be disposed between the semiconductor cores SC.

Referring to FIGS. 2K and 21, the semiconductor cores SC may be grown to form the semiconductor layer 300. The growing of the semiconductor cores SC may include increasing of a temperature of each of the semiconductor cores SC or decreasing of a pressure of the chamber. The semiconductor cores SC may increase in temperature, or the chamber may decrease in pressure to induce the growth of the semiconductor cores SC in the first direction D1 and the second direction D2.

The semiconductor layer 300 may be filled into a space within the recessed part 40_R of the isolation layer 40. The semiconductor layer 300 may be in contact with the upper portion 40_U of the isolation layer 40, the inner wall 40_RIS of the recessed part 40_R, and the top surface 40_RT of the recessed part 40_R. The upper portion 300_U (see FIG. 1B) of the semiconductor layer 300 may be disposed at a level higher than that of the isolation layer 40.

Referring to FIG. 2M, a stressor ST may be provided on the semiconductor layer 300. The stressor ST may include a metallic material. For example, the stressor ST may include Ni or Cu.

Referring to FIG. 2N, the semiconductor layer 300 may be separated from the isolation layer 40. An adhesive layer 200 may be formed on a transfer substrate 100. The separated semiconductor layer 300 may be bonded on the adhesive layer 200.

In some embodiments, before the separated semiconductor layer 300 is bonded on the adhesive layer 200, forming of a preliminary adhesive layer covering the protrusion 300_P (see FIG. 1B) of the separated semiconductor layer 300 may be further performed. The preliminary adhesive layer may include the same material as the adhesive layer 200.

Referring to FIGS. 1A to 1C, the stressor ST may be removed. In some embodiments, the removing of the stressor ST may be performed simultaneously with the bonding of the semiconductor layer 300 on the adhesive layer 200.

The method for manufacturing the semiconductor device according to some embodiments may include the forming of the isolation layer 40 including the two-dimensional material before forming the semiconductor layer 300 to enable easy separation of the semiconductor layer 300.

The method for manufacturing the semiconductor device according to some embodiments may include the forming of the protrusion patterns PP before forming the isolation layer 40. Thus, an area on which the isolation layer 40 and the semiconductor layer 300 are in contact with each other, or an area on which the isolation layer 40 and the semiconductor core SC are in contact with each other may be relatively widened. Thus, in the process of growing the semiconductor core SC into the semiconductor layer 300, the semiconductor core SC and the semiconductor layer 300 may not be separated from the isolation layer 40.

FIG. 3 is a view of a semiconductor device according to some embodiments. The semiconductor device according to FIG. 3 may be similar to the semiconductor device according to FIGS. 1A to 1C, except as described below.

Referring to FIG. 3, an adhesive layer 200a may include a protrusion 200_Pa and a lower portion 200_La. The protrusion 200_Pa of the adhesive layer 200a may include a first sidewall 200_PS1a and a second sidewall 200_PS2a. The first and second sidewalls 200_PS1a and 200_PS2a of the protrusion 200_Pa of the adhesive layer 200a may be inclined with respect to a top surface 200_LTa of the lower portion 200_La of the adhesive layer 200a. The first and second sidewalls 200_PS1a and 200_PS2a of the protrusion 200_Pa of the adhesive layer 200a may be connected to each other. An angle between the first and second sidewalls 200_PS1a and 200_PS2a of the protrusion 200_Pa of the adhesive layer 200a may be greater than about 0° and less than about 90°.

The semiconductor layer 300a may include a protrusion 300_Pa and an upper portion 300_Ua. The protrusion 300_Pa of the semiconductor layer 300a may include a first sidewall 300_PS1a, a second sidewall 300_PS2a, and a bottom surface 300_PBa. The first sidewall 300_PS1a of the protrusion 300_Pa of the semiconductor layer 300a may be connected to the bottom surface 300_PBa of the protrusion 300_Pa of the semiconductor layer 300a. The second sidewall 300_PS2a of the protrusion 300_Pa of the semiconductor layer 300a may be connected to the bottom surface 300_PBa of the protrusion 300_Pa of the semiconductor layer 300a.

The first and second sidewalls 300_PS1a and 300_PS2a of the protrusion 300_Pa of the semiconductor layer 300a may be inclined with respect to the bottom surface 300_PBa of the protrusion 300_Pa of the semiconductor layer 300a. The bottom surface 300_PBa of the protrusion 300_Pa of the semiconductor layer 300a may be contact with the top surface 200_LTa of the bottom surface 200_La of the adhesive layer 200a.

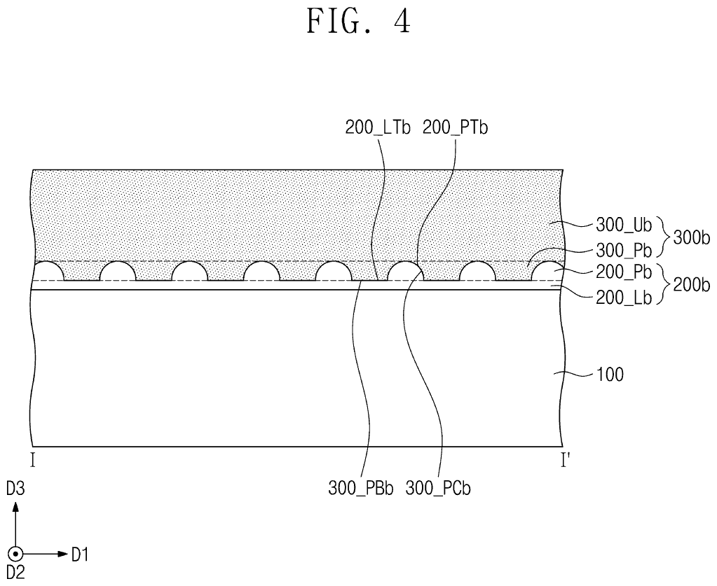

FIG. 4 is a view of a semiconductor device according to some embodiments. The semiconductor device according to FIG. 4 may be similar to the semiconductor device according to FIGS. 1A to 1C, except as described below.

Referring to FIG. 4, an adhesive layer 200b may include a lower portion 200_Lb and a protrusion 200_Pb. A semiconductor layer 300b may include an upper portion 300_Ub and protrusions 300_Pb. The top surface 200_LTb of the lower portion 200_Lb of the adhesive layer 200b may be in contact with a bottom surface 300_PBb of each of the protrusions 300_Pb of the semiconductor layer 300b.

A top surface 200_PTb of the protrusion 200_Pb of the adhesive layer 200b may include a curved surface. The protrusion 200_Pb of the adhesive layer 200b may have a semicircular shape from a cross-sectional viewpoint according to FIG. 4.

The protrusions 300_Pb of the semiconductor layer 300b may include connection surfaces 300_PCb connecting the bottom surfaces 300_PBb of the protrusions 300_Pb of the semiconductor layer 300b to each other. Each of the connection surfaces 300_PCb of the protrusions 300_Pb of the semiconductor layer 300b may include a curved surface. The top surface 200_PTb of the protrusion 200_Pb of the adhesive layer 200b may contact the connection surfaces 300_PCb of the protrusions 300_Pb of the semiconductor layer 300b to each other.

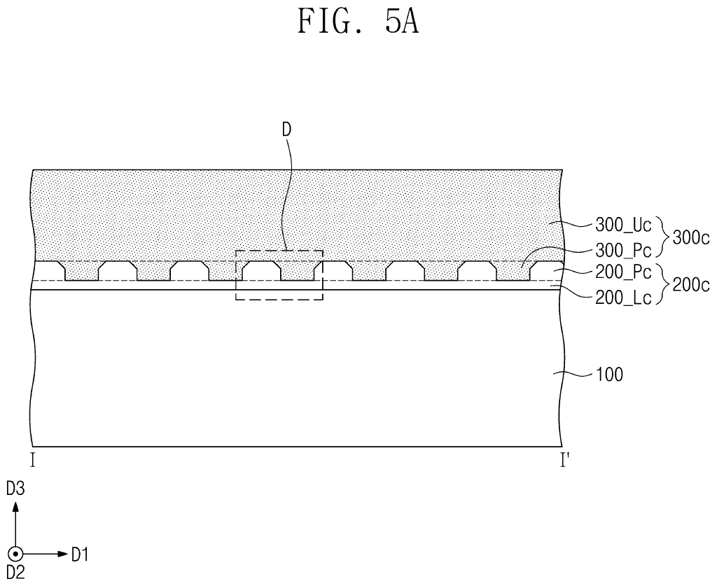

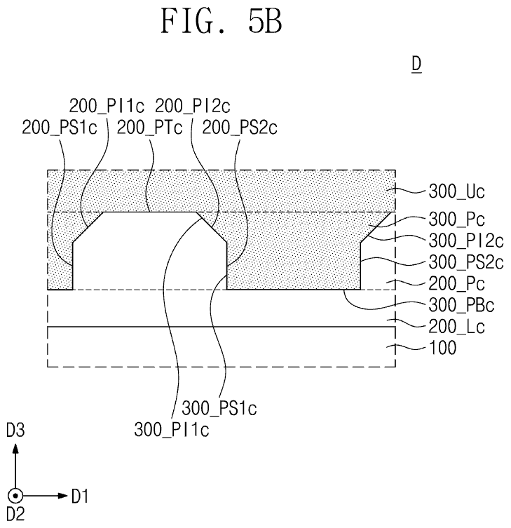

FIG. 5A is a view of a semiconductor device according to some embodiments. FIG. 5D is an enlarged view of an area D of FIG. 5A.

Referring to FIGS. 5A and 5B, an adhesive layer 200c may include a lower portion 200_Lc and a protrusion 200_Pc. A semiconductor layer 300c may include an upper portion 300_Uc and a protrusion 300_Pc.

The protrusion 200_Pc of the adhesive layer 200c may include a first sidewall 200_PS1c, a second sidewall 200_PS2c, a top surface 200_PTc, a first inclined surface 200_Pl1c, and a second inclined surface 200_PI2c. The first and second inclined surfaces 200_Pl1c and 200_PI2c of the protrusion 200_Pc of the adhesive layer 200c may be inclined with respect to a top surface 200_PTc of the protrusion 200_Pc of the adhesive layer 200c.

The first and second inclined surfaces 200_Pl1c and 200_PI2c of the protrusion 200_Pc of the adhesive layer 200c may be spaced apart from the lower portion 200_Lc of the adhesive layer 200c. The first and second inclined surfaces 200_Pl1c and 200_PI2c of the protrusion 200_Pc of the adhesive layer 200c may be spaced apart from each other in the first direction D1.

The top surface 200_PTc of the protrusion 200_Pc of the adhesive layer 200c may connect the first and second inclined surfaces 200_Pl1c and 200_PI2c of the protrusion 200_Pc of the adhesive layer 200c to each other. The first sidewall 200_PS1c of the protrusion 200_Pc of the adhesive layer 200c may connect the first inclined surface 200_Pl1c of the protrusion 200_Pc of the adhesive layer 200c to a top surface of the lower portion 200_Lc of the adhesive layer 200c. The second sidewall 200_PS2c of the protrusion 200_Pc of the adhesive layer 200c may connect the second inclined surface 200_PI2c of the protrusion 200_Pc of the adhesive layer 200c to the top surface of the lower portion 200_Lc of the adhesive layer 200c.

The protrusion 300_Pc of the semiconductor layer 300c may include a top surface 300_PTc, a first sidewall 300_PS1c, a second sidewall 300_PS2c, a first inclined surface 300_Pl1c, and a second inclined surface 300_PI2c. The first and second inclined surfaces 300_Pl1c and 300_PI2c of the protrusion 300_Pc of the semiconductor layer 300c may be inclined with respect to the bottom surface of the upper portion 300_Uc of the semiconductor layer 300c.

The first and second inclined surfaces 300_Pl1c and 300_PI2c of the protrusion 300_Pc of the semiconductor layer 300c may be connected to the upper portion 300_Uc of the semiconductor layer 300c. The first and second inclined surfaces 300_Pl1c and 300_PI2c of the protrusion 300_Pc of the semiconductor layer 300c may be spaced apart from a bottom surface 300_PBc of the protrusion 300_Pc of the semiconductor layer 300c. The first and second inclined surfaces 300_Pl1c and 300_PI2c of the protrusion 300_Pc of the semiconductor layer 300c may be spaced apart from each other in the first direction D1.

The bottom surface 300_PBc of the protrusion 300_Pc of the semiconductor layer 300c may connect the first and second inclined surfaces 300_Pl1c and 300_PI2c of the protrusion 300_Pc of the semiconductor layer 300c to each other. The first sidewall 300_PS1c of the protrusion 300_Pc of the semiconductor layer 300c may connect the first inclined surface 300_Pl1c of the protrusion 300_Pc of the semiconductor layer 300c to the bottom surface 300_PBc of the protrusion 300_Pc of the semiconductor layer 300c. The second sidewall 300_PS2c of the protrusion 300_Pc of the semiconductor layer 300c may connect the second inclined surface 300_PI2c of the protrusion 300_Pc of the semiconductor layer 300c to the bottom surface 300_PBc of the protrusion 300_Pc of the semiconductor layer 300c. The first inclined surface 300_Pl1c of the protrusion 300_Pc of the semiconductor layer 300c may connect the first sidewall 300_PS1c of the protrusion 300_Pc of the semiconductor layer 300c to the bottom surface of the upper portion 300_Uc of the semiconductor layer 300c. The second inclined surface 300_PI2c of the protrusion 300_Pc of the semiconductor layer 300c may connect the second sidewall 300_PS2c of the protrusion 300_Pc of the semiconductor layer 300c to the bottom surface of the upper portion 300_Uc of the semiconductor layer 300c. The first inclined surface 300_Pl1c of the protrusion 300_Pc of the semiconductor layer 300c may be in contact with the second inclined surface 200_PI2c of the protrusion 200_Pc of the adhesive layer 200c. The first sidewall 300_PS1c of the protrusion 300_Pc of the semiconductor layer 300c may be in contact with the second sidewall 200_PS2c of the protrusion 200_Pc of the adhesive layer 200c.

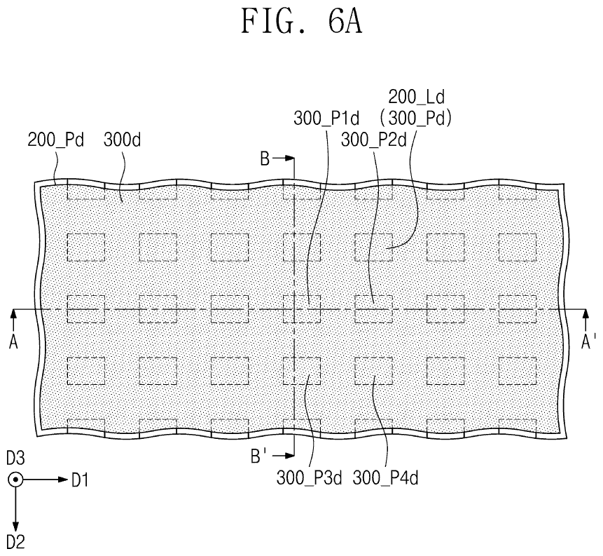

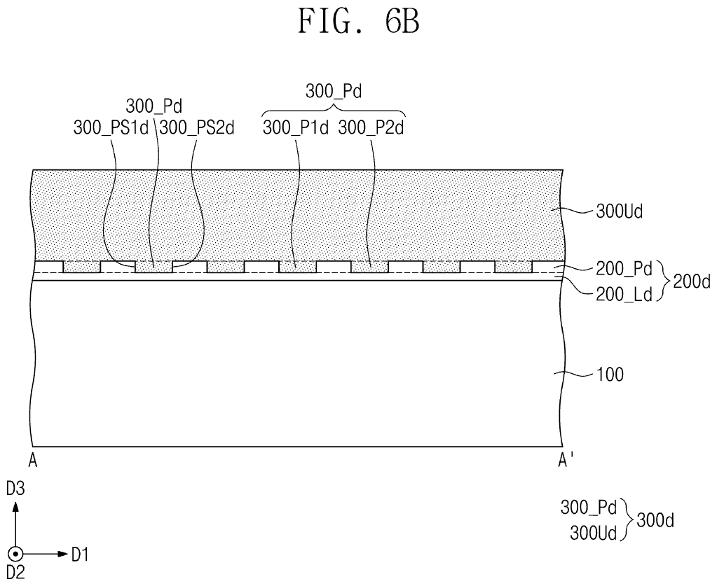

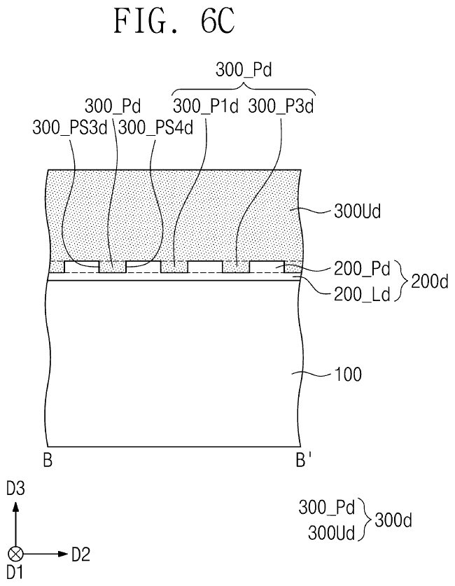

FIG. 6A is a plan view of a semiconductor device according to some embodiments. FIG. 6B is a cross-sectional view taken along line A-A′ of FIG. 6A. FIG. 6C is a cross-sectional view taken along line B-B′ of FIG. 6A. The semiconductor devices according to FIGS. 6a to 6c may be similar to the semiconductor devices according to FIGS. 1A to 1C, except as described below.

Referring to FIGS. 6A, 6B and 6C, an adhesive layer 200d may include a protrusion 200_Pd and a lower portion 200_Ld. A semiconductor layer 300d may include protrusions 300_Pd and an upper portion 300_Ud. The protrusions 300_Pd of the semiconductor layer 300d may include a first protrusion 300_P1d, a second protrusion 300_P2d, a third protrusion 300_P3d, and a fourth protrusion 300_P4d.

The protrusions 300_Pd of the semiconductor layer 300d may be arranged in the first direction D1 and the second direction D2. From a planar viewpoint according to FIG. 6a, the protrusions 300_Pd of the semiconductor layer 300d may have a square shape. The first and second protrusions 300_P1d and 300_P2d of the semiconductor layer 300d may be arranged in the first direction D1. The third and fourth protrusions 300_P3d and 300_P4d of the semiconductor layer 300d may be arranged in the first direction D1. The first and third protrusions 300_P1d and 300_P3d of the semiconductor layer 300d may be arranged in the second direction D2. The second and fourth protrusions 300_P2d and 300_P4d of the semiconductor layer 300d may be arranged in the second direction D2.

The protrusion 300_Pd of the semiconductor layer 300d may include a first sidewall 300_PS1d and a second sidewall 300_PS2d, which are spaced apart from each other in the first direction D1. The protrusion 300_Pd of the semiconductor layer 300d may include a third sidewall 300_PS3d and a fourth sidewall 300_PS4d, which are spaced apart from each other in the second direction D2. The first and second sidewalls 300_S1d and 300_S2d of the protrusion 300_Pd of the semiconductor layer 300d may be opposite to each other. The third and fourth sidewalls 300_S3d and 300_S4d of the protrusion 300_Pd of the semiconductor layer 300d may be opposed to each other.

The protrusion 200_Pd of the adhesive layer 200d may be in contact with the first to fourth sidewalls 300_PS1d, 300_PS2d, 300_PS3d, and 300_PS4d of the protrusion 300_Pd of the semiconductor layer 300d. The protrusions 200_Pd of the adhesive layer 200d may surround the protrusions 300_Pd of the semiconductor layer 300d, respectively.

The semiconductor device according to some embodiments may include the patterns from/into which the adhesive layer and the semiconductor layer protrude and are recessed, and thus, the area on which the adhesive layer and the semiconductor layer are in contact with each other may relatively increase. Thus, the adhesion between the transfer substrate and the semiconductor layer may be more stable and easier.

The method for manufacturing the semiconductor device according to some embodiments may include the forming of the isolation layer including the two-dimensional material before forming the semiconductor layer to easily isolate the semiconductor layer.

The method for manufacturing the semiconductor device according to some embodiments may include the forming of the protrusion patterns before forming the isolation layer. Thus, the area on which the isolation layer and the semiconductor layer are in contact with each other or the area on which the isolation layer and the semiconductor core are in contact with each other may be relatively widened. Therefore, in the process of growing the semiconductor core into the semiconductor layer, the semiconductor core and the semiconductor layer may not be separated from the isolation layer.

Although some embodiments are described with reference to the accompanying drawings, those with ordinary skill in the technical field of the inventive concept pertains will be understood that the present disclosure may be carried out in other specific forms without changing the technical idea or essential features. Therefore, the above-disclosed embodiments are to be considered illustrative and not restrictive.

What is claimed is:

1. A semiconductor device comprising:
a transfer substrate;
a semiconductor layer at a level higher than a level of the transfer substrate; and
an adhesive layer between the transfer substrate and the semiconductor layer,
wherein the adhesive layer comprises a lower portion and first and second protrusions, each of which is disposed at a level higher than a level of the lower portion of the adhesive layer, and
the semiconductor layer comprises an upper portion and first and second protrusions, each of which is disposed at a level lower than a level of the upper portion of the semiconductor layer,
wherein the first and second protrusions of the adhesive layer are in contact with the upper portion of the semiconductor layer,
the first and second protrusions of the semiconductor layer are in contact with the lower portion of the adhesive layer,
the first protrusion of the adhesive layer is disposed between the first and second protrusions of the semiconductor layer, and
the second protrusion of the semiconductor layer is disposed between the first and second protrusions of the semiconductor layer.

2. The semiconductor device of claim 1, wherein the first and second protrusions of the semiconductor layer and the first and second protrusions of the adhesive layer are disposed at the same level.

3. The semiconductor device of claim 1, wherein a sidewall of the first protrusion of the semiconductor layer is in contact with a sidewall of the first protrusion of the adhesive layer.

4. The semiconductor device of claim 1, wherein the adhesive layer comprises a metal material.

5. The semiconductor device of claim 1, wherein the lower portion, the first protrusion, and the second protrusion of the adhesive layer are connected to each other to be integrated with each other, and
the upper portion, the first protrusion, and the second protrusion of the semiconductor layer are connected to each other to be integrated with each other.

6. The semiconductor device of claim 1, wherein a sidewall of the first protrusion of the semiconductor layer is connect a bottom surface of the first protrusion of the semiconductor layer to a bottom surface of the upper portion of the semiconductor layer.

7. The semiconductor device of claim 1, wherein the first protrusion of the semiconductor layer comprises a first sidewall and a second sidewall,
wherein the first and second sidewalls of the first protrusion are inclined with respect to a bottom surface of the first protrusion of the semiconductor layer.

8. The semiconductor device of claim 7, wherein an angle between the first and second sidewalls of the first protrusion of the semiconductor layer is greater than about 0° and less than about 90°.

9. The semiconductor device of claim 1, wherein each of sidewalls of the first and second protrusions of the semiconductor layer comprises a curved surface.

10. A semiconductor device comprising:
a transfer substrate;
an adhesive layer that is in contact with the transfer substrate; and
a semiconductor layer that is in contact with the adhesive layer,
wherein the adhesive layer comprises a lower portion and first and second protrusions that is protruding from the lower portion of the adhesive layer,
wherein the first and second protrusions of the adhesive layer are spaced apart from each other,
the semiconductor layer covers the first and second protrusions of the adhesive layer, and
a portion of the semiconductor layer is disposed between the first and second protrusions of the adhesive layer.

11. The semiconductor device of claim 10, wherein the semiconductor layer comprises an upper portion, and first and second protrusions protruding from the upper portion of the semiconductor layer,
wherein the first and second protrusions of the semiconductor layer are spaced apart from each other, and
the first protrusion of the adhesive layer is disposed between the first and second protrusions of the semiconductor layer.

12. The semiconductor device of claim 11, wherein a thickness of each of the first and second protrusions of the semiconductor layer is less than a thickness of the upper portion of the semiconductor layer.

13. The semiconductor device of claim 11, wherein a thickness of each of the first and second protrusions of the semiconductor layer is the same as a thickness of each of the first and second protrusions of the adhesive layer.

14. The semiconductor device of claim 11, wherein the first and second protrusions of the semiconductor layer are spaced apart from each other in a first direction, and
the semiconductor layer further comprises third and fourth protrusions at the same level as the first and second protrusions of the semiconductor layer,
wherein the third and fourth protrusions are spaced apart from each other in the first direction, and
the first and third protrusions are spaced apart from each other in a second direction intersecting the first direction.

15. A method for manufacturing a semiconductor device, the method comprising:
patterning a growth substrate to form a first protrusion pattern and a second protrusion pattern;
forming an isolation layer covering the first and second protrusion patterns, wherein the isolation layer comprises a first recessed part between the first and second protrusion patterns;
forming a semiconductor core on the first recessed part of the isolation layer;
growing the semiconductor color to form a semiconductor layer, wherein a portion of the semiconductor layer is disposed at a level higher than a level of the isolation layer; and
separating the semiconductor layer from the isolation layer.

16. The method of claim 15, wherein the isolation layer conformally covers the first and second protrusion patterns.

17. The method of claim 15, wherein the isolation layer comprises a two-dimensional material.

18. The method of claim 15, further comprising, before separating the semiconductor layer from the isolation layer, providing a stressor comprising a metal material on a top surface of the semiconductor layer.

19. The method of claim 15, further comprising:
providing a transfer substrate;
forming an adhesive layer on the transfer substrate; and
transferring the separated semiconductor layer onto the adhesive layer.

20. The method of claim 15, wherein the isolation layer further comprises a second recessed part spaced apart from the first recessed part, and an upper portion at a level higher than a level of each of the first and second recessed parts,
wherein the upper portion of the isolation layer connects the first and second recessed parts of the isolation layer to each other, and
the first protrusion pattern is disposed between the first and second recessed parts.
